(19) United States
(12) Patent Application Publication
(10) Pub. No.: US 2025/0079197 A1
(43) Pub. Date: Mar. 6, 2025

(54) SUBSTRATE TREATING APPARATUS AND SUBSTRATE TREATING METHOD

(71) Applicant: SEMES CO., LTD., Cheonan-si (KR)

(72) Inventors: Pil Kyun HEO, Yongin-si (KR); Min Woo KIM, Seoul (KR); Hyung Seok KANG, Suwon-si (KR); Anton KORIAKIN, Suwon-si (KR); Joon Hee LEE, Suwon-si (KR)

(73) Assignee: SEMES CO., LTD., Cheonan-si (KR)

(21) Appl. No.: 18/815,987

(22) Filed: Aug. 27, 2024

(30) Foreign Application Priority Data
Aug. 30, 2023 (KR) 10-2023-0114592

(51) Int. Cl. H01L 21/67; H01L 21/02

(52) U.S. Cl. CPC H01L 21/67034; H01L 21/02101

(57) ABSTRACT

Disclosed are an apparatus for treating a substrate and a method of treating a substrate using a supercritical fluid. The apparatus includes: a chamber for providing a treatment space for treating a substrate; and a treatment fluid supply unit for supplying a treatment fluid to the treatment space, in which treatment fluid supply unit includes: a tank for storing the treatment fluid; a heating unit for heating the treatment fluid in the tank to convert the treatment fluid from a first state to a second state; an inlet line for introducing the treatment fluid in the first state into the tank; a supply line for supplying the treatment fluid of the second state from the tank to the chamber; a circulation line for circulating the treatment fluid in the tank; a first valve installed in the circulation line; and a temperature drop member installed in the circulation line to lower a temperature of the treatment fluid flowing through the circulation line.

### CROSS-REFERENCE TO RELATED APPLICATIONS

This application claims priority to and the benefit of Korean Patent Application No. 10-2023-0114592 filed in the Korean Intellectual Property Office on Aug. 30, 2023, the entire contents of which are incorporated herein by reference.

### TECHNICAL FIELD

The present invention relates to an apparatus for treating a substrate and a method of treating a substrate using a supercritical fluid.

### BACKGROUND ART

To manufacture semiconductor devices, a desired pattern is formed on a substrate, such as a wafer, through various processes, such as photography, etching, ashing, ion implantation, and thin film deposition. A variety of treatment solutions and treatment gas are used in each process. In addition, a drying process is performed on the substrate to remove the treatment solution used to treat the substrate from the substrate.

Generally, the drying process for removing the treatment solution from the substrate includes removing the treatment solution residual on the substrate with centrifugal force by rotation of the substrate, or removing the treatment solution residual on the substrate by using a supercritical fluid.

A supercritical drying process involves loading a substrate into a chamber capable of maintaining a high-pressure, high-temperature atmosphere, and then supplying supercritical carbon dioxide to the substrate to remove any residual treatment solution (for example, organic solvent, or developer solvent) from the substrate.

To carry out the supercritical drying process, the treatment fluid of the supercritical state is supplied from a tank storing the treatment fluid of the supercritical state to the chamber performing the supercritical drying process, and then the tank is replenished with the treatment fluid of the liquid state. Since the liquid has a relatively lower temperature than the treatment fluid of the supercritical state, the temperature of the treatment fluid of the supercritical state is lowered. In this case, the result of the supercritical drying process is sensitive to the temperature of the treatment fluid of the supercritical state, so it is necessary to constantly control the temperature of the treatment fluid of the supercritical state. Thus, in order to compensate for the drop in temperature and change in phase of the fluid from the liquid state to a supercritical state, a process of heating with a heater installed in the tank is accompanied. However, during the heating process, the temperature of the treatment fluid of the supercritical state may rise above the temperature required for the drying process. Accordingly, the pressure of the tank is also increased, and in general, in order to control the temperature of the treatment fluid of the supercritical state, the treatment fluid of the supercritical state is discharged to the outside of the tank when the tank reaches a set pressure. After the discharge, the process is repeated by replenishing the tank with the low-temperature liquid and controlling the temperature of the treatment fluid of the supercritical state. In this typical method, there is a problem that the treatment fluid of the supercritical state is wasted in the process of controlling the temperature of the treatment fluid of the supercritical state in the tank.

### SUMMARY OF THE INVENTION

The present invention has been made in an effort to provide a substrate treating apparatus and a substrate treating method, which are capable of efficiently treating a substrate.

The present invention has also been made in an effort to provide a substrate treating apparatus and a substrate treating method, which are capable of efficiently controlling a temperature of a supercritical fluid within a tank.

The present invention has also been made in an effort to provide a substrate treating apparatus and a substrate treating method, which are capable of efficiently decreasing waste of a supercritical fluid within a tank.

The object of the present invention is not limited thereto, and other objects not mentioned will be clearly understood by those of ordinary skill in the art from the following description.

An exemplary embodiment of the present invention provides an apparatus for treating a substrate, the apparatus including: a chamber for providing a treatment space for treating a substrate; and a treatment fluid supply unit for supplying a treatment fluid to the treatment space, in which treatment fluid supply unit includes: a tank for storing the treatment fluid; a heating unit for heating the treatment fluid in the tank to change the treatment fluid from a first state to a second state; an inlet line for introducing the treatment fluid in the first state into the tank; a supply line for supplying the treatment fluid of the second state from the tank to the chamber; a circulation line for circulating the treatment fluid in the tank; a first valve installed in the circulation line; and a temperature drop member installed in the circulation line to lower a temperature of the treatment fluid flowing through the circulation line.

According to the exemplary embodiment, the temperature drop member may include a temperature drop passage having a narrower area than an area of a passage through which the treatment fluid flows in the circulation line.

According to the exemplary embodiment, the temperature drop member may include an orifice.

According to the exemplary embodiment, the temperature drop passage may include: a contraction portion having a progressively narrower cross-sectional area along a longitudinal direction of the temperature drop passage in a direction from upstream to downstream; and an expansion portion having a progressively wider cross-sectional area along the longitudinal direction of the passage in a direction from upstream to downstream, and the contraction portion may be located upstream of the expansion portion.

According to the exemplary embodiment, the temperature drop passage may further include a connection portion connecting the contraction portion and the expansion portion, and the connection portion may have a constant cross-sectional area along the longitudinal direction of the temperature drop passage.

According to the exemplary embodiment, the temperature drop member may be provided to change the treatment fluid of the first state to the treatment fluid of a third state.

According to the exemplary embodiment, the first state may be a liquid state, the second state may be a supercritical state, and the third state may be a gaseous state.

According to the exemplary embodiment, the circulation line may be provided in a separation state from the supply line.

According to the exemplary embodiment, the apparatus may further include: a pressure sensor for measuring a pressure in the tank; and a controller, in which the controller may receive a measurement value measured from the pressure sensor and control the first valve based on the measurement value.

According to the exemplary embodiment, the controller may control the first valve to open when the measurement value exceeds a preset pressure.

According to the exemplary embodiment, the apparatus may further include: a second valve installed in the supply line to open and close the supply line; a temperature sensor for measuring a temperature of the treatment fluid; and a controller, in which the controller may control the second valve to open when the temperature measured by the temperature sensor satisfies a preset range when treating the substrate.

Still another exemplary embodiment of the present invention provides a method of treating a substrate, the method including: an introduction operation of introducing a treatment fluid of a first state into a tank; a state change operation of changing the treatment fluid of the first state to a second state; and a supply operation of supplying the treatment fluid of the second state into a chamber treating a substrate, in which after the state change operation, a circulation operation is performed to circulate the treatment fluid of the second state through a circulation line connected to the tank such that a temperature of the treatment fluid of the second state in the tank is lowered when a pressure in the tank exceeds a preset pressure.

According to the exemplary embodiment, in the circulation operation, an area of the passage may be changed while the treatment fluid of the second state is flowing so that the treatment fluid of the second state may be changed to a treatment fluid of a third state by a temperature drop.

According to the exemplary embodiment, in the circulation operation, the treatment fluid of the second state may be compressed, and the compressed treatment fluid of the second state may be expanded again, so that temperature drop of the treatment fluid of the second state may be achieved.

According to the exemplary embodiment, the second state may be a supercritical state, and the third state may be a gaseous state.

According to the exemplary embodiment, the supply operation may include: measuring a temperature of the treatment fluid of the second state when treating the substrate, and when the measured temperature value satisfies a preset temperature range, the treatment fluid of the second state may be supplied into the chamber.

According to the exemplary embodiment, the treatment may be a treatment of drying the substrate with the treatment fluid of the second state.

Still another exemplary embodiment of the present invention provides an apparatus for treating a substrate, the apparatus including: a chamber for providing a treatment space for treating a substrate; and a treatment fluid supply unit for supplying a treatment fluid to the treatment space, in which the treatment fluid supply unit includes: a tank for storing the treatment fluid; a pressure sensor for measuring a pressure in the tank; a heating unit for heating the fluid to change the treatment fluid in the tank from a liquid state to a supercritical state, an inlet line for introducing the treatment fluid of the liquid state into the tank; a circulation line provided in a separation state from the supply line, and for circulating the treatment fluid in the tank; a first valve installed in the circulation line to open and close the circulation line; a temperature drop member installed in the circulation line to drop the temperature of the treatment fluid flowing through the circulation line; a supply line for supplying the treatment fluid of the supercritical state from the tank to the chamber; and a controller, in which the temperature drop member changes the treatment fluid of the supercritical state to a gaseous state, and the controller receives a pressure value measured from the pressure sensor and, and opens the first valve when the pressure value exceeds a preset pressure.

According to the exemplary embodiment, the temperature drop member may include: a contraction portion progressively smaller in a direction from upstream to downstream of the circulation line; an extension portion progressively larger in a direction from upstream to downstream of the circulation line; and a connection portion connecting the contraction portion and the expansion portion, and the contraction portion is located upstream of the expansion portion.

According to the exemplary embodiment, the temperature drop member may include an orifice.

According to the exemplary embodiment of the present invention, it is possible to efficiently treat a substrate.

Further, according to the exemplary embodiment of the present invention, it is possible to efficiently maintain a temperature of a treatment fluid of a supercritical state.

Further, according to the exemplary embodiment of the present invention, it is possible to efficiently store a treatment fluid of a supercritical state.

Further, according to the exemplary embodiment of the present invention, it is possible to secure reproducibility in a drying treatment.

The effects of the invention are not limited to those described above, and those not described will be apparent to those skilled in the art from this specification and the accompanying drawings.

### BRIEF DESCRIPTION OF THE DRAWINGS

FIG. 1 is a top plan view schematically illustrating a substrate treating apparatus according to an exemplary embodiment of the present invention.

FIG. 2 is a cross-sectional view schematically illustrating an exemplary embodiment of a liquid treating chamber of FIG. 1.

FIG. 3 is a cross-sectional view schematically illustrating an exemplary embodiment of a drying chamber of FIG. 1.

FIG. 4 is a cross-sectional view schematically illustrating an exemplary embodiment of a treatment fluid supply unit of FIG. 3.

FIG. 5 is a cross-sectional view schematically illustrating an exemplary embodiment of a temperature drop member provided in the treatment fluid supply unit of FIG. 4.

FIG. 6 is a flow chart illustrating a substrate treating method according to an exemplary embodiment of the present invention.

FIG. 7 is a graph illustrating the temperature change over time of a treatment fluid stored in a tank according to an exemplary embodiment of the present invention.

FIG. 8 is a cross-sectional view schematically illustrating another exemplary embodiment of the temperature drop member of FIG. 5.

FIG. 9 is a cross-sectional view schematically illustrating another exemplary embodiment of the temperature drop member of FIG. 5.

FIG. 10 is a cross-sectional view schematically illustrating another exemplary embodiment of the temperature drop member of FIG. 5.

FIG. 11 is a cross-sectional view schematically illustrating another exemplary embodiment of the temperature drop member of FIG. 5.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

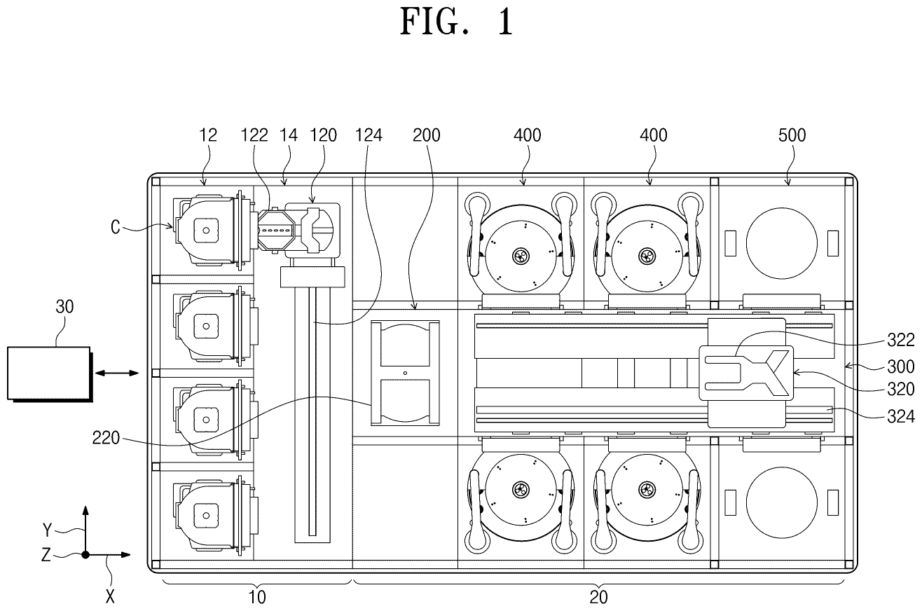

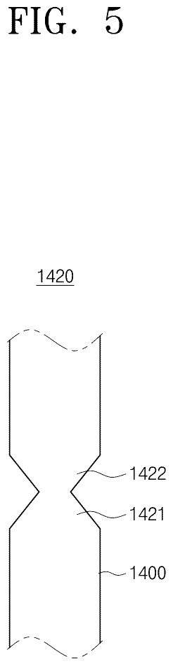

Hereinafter, an exemplary embodiment of the present invention will be described with reference to FIGS. 1 to 11.

FIG. 1 is a top plan view schematically illustrating a substrate treating apparatus according to an exemplary embodiment of the present invention.

Referring to FIG. 1, the substrate treating apparatus includes an index module 10, a treating module 20, and a controller 30. When viewed from above, the index module 10 and the treating module 20 are disposed along one direction. Hereinafter, a direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from a container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. With respect to the index frame 14, the load port 12 is located at a side opposite to the treating module 20. The containers C in which the substrates W are accommodated are placed in the load ports 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. The plurality of hands 122 is provided while being spaced apart from each other in the vertical direction, and is capable of independently moving forward and backward.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treatment process of treating the substrate W with a liquid by supplying the liquid onto the substrate W. The drying chamber 500 performs a drying process of removing the liquid residual on the substrate W. The transfer chamber 300 transfers the substrate W between the buffer unit 200, the liquid treating chamber 400, the drying chamber 500, and a post-treating chamber 600.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

In one example, the liquid treating chambers 400 are disposed on opposite sides of the transfer chamber 300 and the drying chambers 500 are disposed on opposite sides of the transfer chamber 300, and the liquid treating chambers 400 may be disposed closer to the buffer unit 200 than the drying chambers 500.

At one side and/or the other side of the transfer chamber 300, the liquid treating chambers 400 may be provided in an arrangement of A×B (each of A and B is 1 or a natural larger than 1) in the first direction X and the third direction Z. Further, at one side and/or the other side of the transfer chamber 300, the drying chambers 500 may be provided in number of C×D (each of C and D is 1 or a natural number larger than 1) in the first direction X and the third direction Z. Further, at one side and/or the other side of the transfer chamber 300, the post-treating chambers 600 may be provided in number of E×F (each of E and F is 1 or a natural number larger than 1) in the first direction X and the third direction Z.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

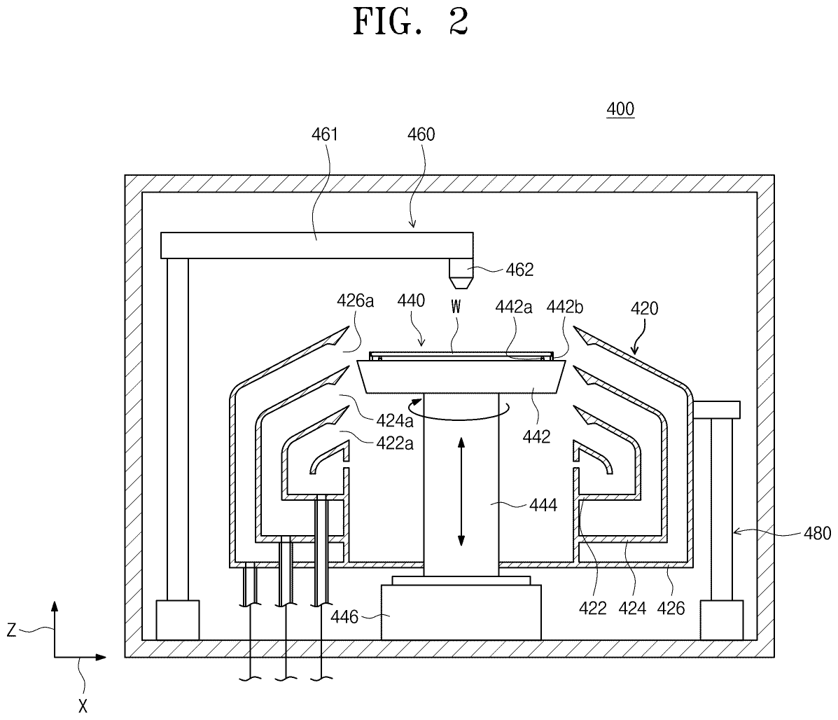

FIG. 2 is a cross-sectional view schematically illustrating an exemplary embodiment of the liquid treating chamber of FIG. 1.

Referring to FIG. 2, the liquid treating chamber 400 includes a housing 410, a cup 420, a support unit 440, a liquid supply unit 460, and a lifting unit 480.

The housing 410 may have an interior space where the substrate W is treated. The housing 410 may have a generally hexahedral shape. For example, the housing 410 may have a cuboidal shape. Further, the housing 410 may have an opening (not illustrated) through which the substrate W is loaded or unloaded. Further, the housing 410 may be equipped with a door (not illustrated) that selectively opens and closes the opening.

The cup 420 may have a barrel shape with an open top. The cup 420 has a treatment space, and the substrate W may be liquid-treated within the treatment space. The support unit 440 supports the substrate W in the treatment space. The liquid supply unit 460 supplies a treatment solution onto the substrate W supported on the support unit 440. The treatment solution may be provided in a plurality of types and may be supplied sequentially onto the substrate W. The lifting unit 480 adjusts a relative height between the cup 420 and the support unit 440.

According to the example, the cup 420 includes a plurality of collection containers 422, 424, and 426. Each of the collection containers 422, 424, and 426 has a collection space for collecting the liquid used for the treatment of the substrate. Each of the collection containers 422, 424, and 426 is provided in a ring shape surrounding the support unit 440. As the liquid treating process proceeds, the treatment solution scattered by the rotation of the substrate W enters the collection space through inlets 422a, 424a, and 426a of the respective collection containers 422, 424, and 426. In one example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. The second inlet 424a, through which the liquid is introduced into the second collection container 424, may be located above the first inlet 422a, through which the liquid is introduced into the first collection container 422, and the third inlet 426a, through which the liquid is introduced into the third collection container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear face of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The driving shaft 444 is driven by a driver 446, is connected to the center of the bottom surface of the substrate W, and rotates the support plate 442 with respect to the central axis thereof.

In one example, the liquid supply unit 460 may include a nozzle 462. The nozzle 462 may supply the treatment solution to the substrate W. The treatment solution may be a chemical, rinse solution, or organic solvent. The chemical may be a chemical having the nature of strong acid or strong base. In addition, the rinse solution may be pure water. Furthermore, the organic solvent may be isopropyl alcohol (IPA). Additionally, the treatment solution supplied by the liquid supply unit 460 may be a developer. For example, the developer supplied by the liquid supply unit 460 may comprise N-Butyl Acetate.

Additionally, the liquid supply unit 460 may include a plurality of nozzles 462, each of which may supply a different type of treatment solution. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply a rinse solution from the other one of the nozzles 462 to the substrate W and then supply an organic solvent from another one of the nozzles 462. Thus, the rinse solution supplied to the substrate W may be replaced with an organic solvent having low surface tension. Additionally, any one of the nozzles 462 may supply a developer.

The lifting unit 480 moves the cup 420 in the up and down direction. By the up and down movement of the cup 420, a relative height between the cup 420 and the substrate W is changed. Accordingly, since the collection containers 422, 424, and 426 for collecting the treatment solution are changed according to the type of the liquid supplied to the substrate W, the liquids may be separated and collected. Unlike the description, the cup 420 may be fixedly installed, and the lifting unit 480 may move the support unit 440 in the up and down direction.

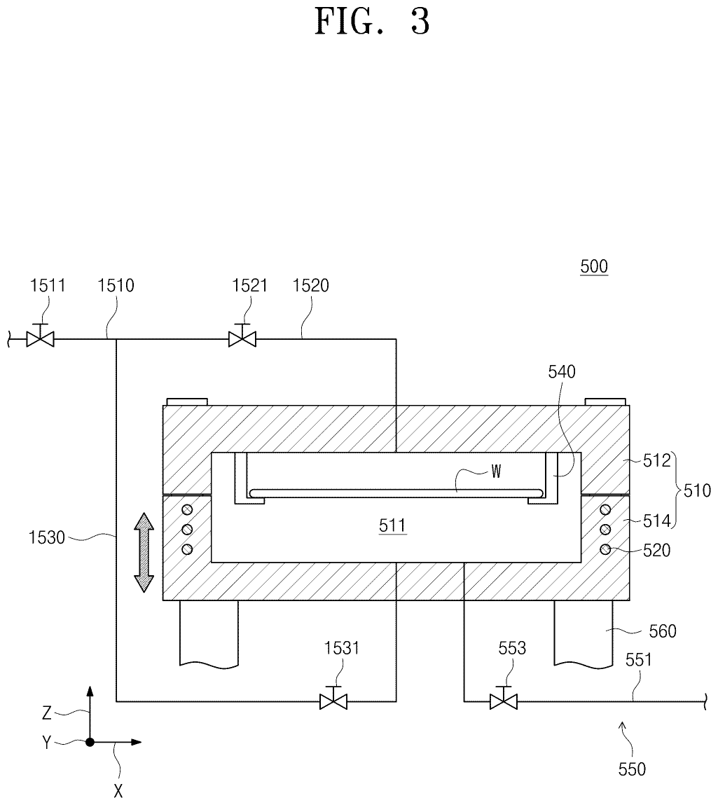

FIG. 3 is a cross-sectional view schematically illustrating an exemplary embodiment of the drying chamber of FIG. 1.

Referring to FIG. 3, the drying chamber 500 according to the exemplary embodiment of the present invention may remove the treatment solution remaining on the substrate W by using a treatment fluid SC of the supercritical state. The treatment solution removed may be an organic solvent. Further, the treatment fluid SC may include carbon dioxide (CO2).

The drying chamber 500 may include a body 510, a heating member 520, a treatment fluid supply unit 1000, a support member 540, a treatment fluid discharge unit 550, and a lifting member 560.

The body 510 may have an interior space 511 in which the substrate W is treated. The body 510 may provide an interior space 511 in which the substrate W is treated. The body 510 may provide the interior space 511 in which the substrate W is dry processed by the treatment fluid SC of the supercritical state.

The body 510 may include an upper body 512 and a lower body 514. The upper body 512 and the lower body 514 may be combined with each other to form the interior space 511. Any one of the upper body 512 and the lower body 514 may be coupled to the lifting member 560 to move in the up and down direction. For example, the lower body 514 may be coupled to the lifting member 560 to move in the up and down direction by the lifting member 560. Accordingly, the interior space 511 of the body 510 may be optionally sealed. In the above-described example, the case where the lower body 514 is coupled to the lifting member 560 to move in the up and down direction has been described as an example, but the present invention is not limited thereto. For example, the upper body 512 may be coupled to the lifting member 560 to move in the up and down direction.

The heating member 520 may heat the treatment fluid SC supplied to the interior space 511. The heating member 520 may increase the temperature of the interior space 511 of the body 510. By increasing the temperature of the internal space 511 by the heating member 520, the treatment fluid SC supplied to the interior space 511 may be changed to a supercritical state, or may remain in a supercritical state.

In addition, the heating member 520 may be embedded in the body 510. For example, the heating element 520 may be embedded in at least one of the upper body 512 and the lower body 514. For example, the heating member 520 may be provided in each of the upper body 512 and the lower body 514. However, the present invention is not limited thereto, and the heating member 520 may be provided at various positions capable of increasing the temperature of the interior space 511. Also, the heating member 520 may be a heater. However, the present invention is not limited thereto, and the heating member 520 may be variously modified into a known device capable of increasing the temperature of the interior space 511.

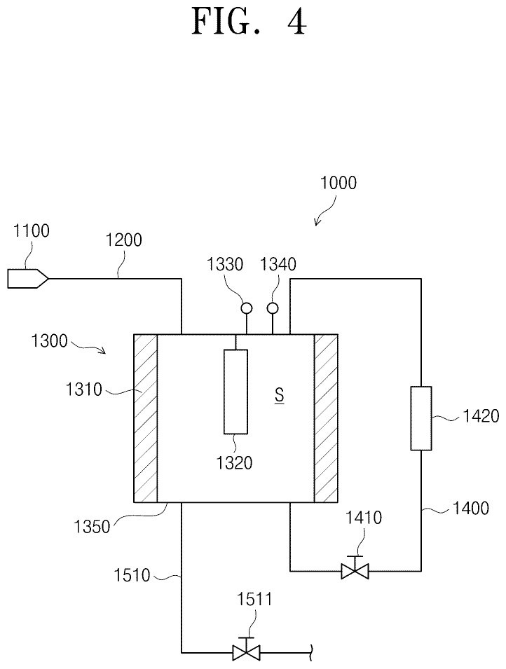

FIG. 4 is a cross-sectional view schematically illustrating an exemplary embodiment of a treatment fluid supply unit of FIG. 3.

The treatment fluid supply unit 1000 may supply the treatment fluid SC to the interior space 511 of the body 510. The treatment fluid supply unit 1000 may include a treatment fluid supply source 1100, an inlet line 1200, a tank 1300, a circulation line 1400, and a supply line 1500.

The treatment fluid supply source 1100 may store the treatment fluid SC that is supplied to the interior space 511 of the body 510, or may supply the treatment fluid SC to the interior space 511. The treatment fluid supply source 1100 may supply the treatment fluid SC to the interior space 511 via the inlet line 1200, the tank 1300, the first supply line 1520, and/or the second supply line 1530. The treatment fluid SC stored in the treatment fluid supply source 1100 may be in a liquid state. In one example, the treatment fluid SC may include carbon dioxide (CO2) in a liquid state.

The inlet line 1200 supplies the treatment fluid SC from the treatment fluid supply source 1100 to the tank 1200. The inlet line 1200 connects the treatment fluid supply source 1100 and the tank 1300. In one example, the treatment fluid SC including carbon dioxide in a liquid state is introduced into the tank.

The tank 1300 may store the treatment fluid SC. The tank 1300 may include an external heater 1310, an internal heater 1320, a temperature sensor 1330, a pressure sensor 1340, and a body 1350. Further, the body 1350 may be connected to a circulation line 1400 and a main supply line 1500, which will be described later. The body 1350 provides a storage space S for storing the treatment fluid SC. The treatment fluid SC may be changed to the supercritical state and maintained in the supercritical state within the storage space S.

The external heater 1310 heats the tank 1300 from the outside of the tank 1300. The external heater 1310 is installed on the outside of the tank 1300. In one example, the external heater 1310 may be shaped to surround an outer wall of the tank 1300. Additionally, the external heater 1310 may be buried within the body 1360. However, without limitation, the external heater 1310 may be provided at various locations outside of the tank 1300 that may raise the temperature of the storage space S. Further, the external heater 1310 may be a heater. However, without limitation, the external heater 1310 may be any known device that may raise the temperature of the storage space S.

The internal heater 1320 heats the treatment fluid SC stored inside the interior of the tank 1300. The internal heater 1320 is installed inside the tank 1300. In one example, the internal heater 1320 may be provided in the form of a rod that runs along the longitudinal direction of the tank 1300. Additionally, the internal heater 1320 may be installed in the center of the tank 1300. However, without limitation, the internal heater 1320 may be provided at various locations that may raise the temperature of the treatment fluid SC. Further, the internal heater 1320 may be a heater. However, without limitation, the internal heater 1320 may be variously modified to any known device capable of raising the temperature of the treatment fluid SC.

In one example, the external heater 1310 and the internal heater 1320 may increase the temperature of the storage space S of the tank 1300 so that the treatment fluid SC supplied to the tank 1300 may be changed to or remain in a supercritical state.

The temperature sensor 1330 measures the temperature of the treatment fluid SC. In one example, the temperature sensor may be installed on the top of the tank 1300. However, the present invention is not limited thereto, and any location where the temperature of the treatment fluid SC may be measured is sufficient. The temperature sensor 1330 transmits the measured temperature of the treatment fluid SC to the controller 30.

The pressure sensor 1340 measures the pressure in the tank 1300. In one example, the pressure sensor may be installed on the top of the tank 1300. However, the present invention is not limited thereto, and any location where the pressure of the tank 1300 may be measured is sufficient. The pressure sensor 1340 may transmit the measured pressure to the controller 30. The controller 30 may control the temperature of the treatment fluid SC in the tank 1300 based on the pressure value measured by the pressure sensor 1340, as described later.

The circulation line 1400 circulates the treatment fluid SC in the tank 1300 to the outside of the tank 1300. One end and the other end of the circulation line are directly connected to the tank. For example, one end of the circulation line is connected to the bottom wall of the tank, and the other end of the circulation line is connected to the top wall of the tank. A first valve 1410 and a temperature drop member 1420 are installed in the circulation line 1400.

The first valve 1410 is installed upstream of the temperature drop member 1420, which will be described later. The first valve 1410 may be an on/off valve, such as an open/close valve. Optionally, the first valve 1410 may be a flow control valve. Upon opening or closing of the first valve 1410, the treatment fluid SC may flow in the circulation line 1400. The first valve 1410 may be controlled by a controller 30. The controller 30 may determine whether to open or close the first valve 1410 based on the pressure value in the tank 1300 transmitted from the pressure sensor 1340.

The temperature drop member 1420 reduces the temperature of the treatment fluid SC flowing through the circulation line 1400. The temperature drop member 1420 is installed downstream of the first valve 1410. In one example, the temperature drop member 1420 includes a contraction portion 1421 having a progressively smaller cross-sectional area along a longitudinal direction of the circulation line 1400 and an expansion portion 1422 having a progressively larger cross-sectional area along a longitudinal direction of the circulation line 1400. The contraction portion 1421 is located upstream of the expansion portion 1422. Further, the contraction portion 1421 and the expansion portion 1422 may be connected to each other.

The supply line 1500 may include a main supply line 1510, a first supply line 1520, and a second supply line 1530. The main supply line is connected directly to the bottom wall of the tank. A second valve 1511 is installed on the main supply line 1510. The first supply line 1520 is equipped with a first supply valve 1521. Further, the second supply line 1530 is equipped with a second supply valve 1531. The second valve 1511, the first supply valve 1521, and the second supply valve 1531 may be on/off valves, such as an open/close valve. Optionally, the second valve 1511, the first supply valve 1521 and the second supply valve 1531 may be flow control valves. Depending on the opening and closing of the first supply valve 1521 and the second supply valve 1531, the treatment fluid SC may optionally flow in the first supply line 1520 or the second supply line 1530.

The first supply line 1520 is coupled to the upper body 510. The first supply line 1520 is provided to supply the treatment fluid SC towards the top surface of the substrate W. The treatment fluid SC supplied from the first supply line 1520 may be supplied into the treatment space in a top-to-bottom direction.

The second supply line 1530 is coupled to the lower body. The second supply line may be provided to supply treatment fluid into the treatment space in a bottom-to-top direction.

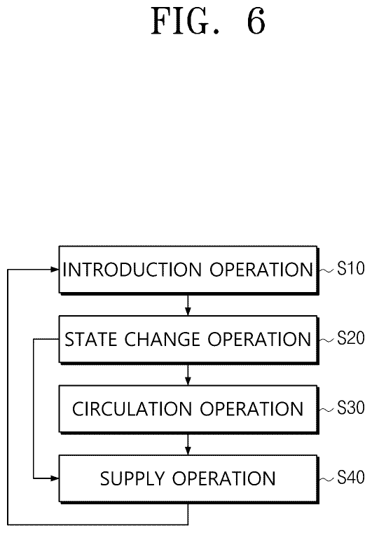

In the following, a method of dry treating the substrate W in the drying chamber 500 will be described in detail. FIG. 6 is a flow chart illustrating a substrate treating method according to an exemplary embodiment of the present invention. The controller 30 may control the substrate treating apparatus so as to perform a substrate treating method to be described below. The controller 30 may control components provided in the treatment fluid supply unit 1000 to perform the substrate treating method described herein. For example, the components may be the first supply valve 1521, the second supply valve 1531, the first valve 1410, the second valve external heater 1310, the internal heater 1320, and the like. The controller 30 may also control each of the valves 1410, 1510, 1521, and 1531 based on temperature and pressure transmitted from the temperature sensor 1330 and the pressure sensor 1340.

Further, the controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treating conditions. Further, the user interface and the storage unit may be connected to the process control unit. The treating recipe may be stored in a storage medium in the storage unit, and the storage medium may be a hard disk, and may also be a portable disk, such as a CD-ROM or a DVD, or a semiconductor memory, such as a flash memory.

The controller 30 receives the pressure of the tank 1300 from the pressure sensor 1340. The controller 30 controls the first valve 1410 to open when the transmitted pressure value exceeds a preset pressure. When the first valve 1410 is opened, the treatment fluid SC in the tank 1300 is supplied into the circulation line 1400. The treatment fluid SC passes through the temperature drop member 1420 in the circulation line 1400. After passing through the temperature drop member 1420, the treatment fluid of the supercritical state is supplied back into the tank 1400. As the treatment fluid SC of the supercritical state passes through the temperature drop member 1420, the treatment fluid SC of the supercritical state temperature decreases and changes state to the gaseous state. The temperature of the treatment fluid SC of the supercritical state is decreased while the treatment fluid SC of the supercritical state is supplied again to the tank in the gaseous state having a relatively low temperature. Thus, according to the exemplary embodiment of the present invention, the temperature of the treatment fluid may be controlled and the pressure in the tank 1300 may be reduced without discharging the treatment fluid SC, thereby reducing the consumption of the treatment fluid SC.

The substrate treating method of the present invention may include an introduction operation S10, a state change operation S20, and a supply operation S40.

In the introduction operation S10, a first state of treatment fluid SC is introduced into the tank 1300 via the inlet line 1000 from the treatment fluid supply source 1100. The treatment fluid SC may be at a relatively lower temperature than the treatment fluid SC stored in the tank 1300. In one example, the first state may be a liquid state. Hereinafter, it is described that the first state is a liquid state.

In the state change operation S20, the external heater 1310 and the internal heater 1320 heat the treatment fluid SC. The controller 30 may control the external heater 1310 and the internal heater 1320 such that the temperature of the treatment fluid SC is in a preset temperature range. Accordingly, the treatment fluid SC is state-changed to a second state in the tank. For example, the second state may be a supercritical state. Hereinafter, it is described that the second state is a supercritical state. Further, the pressure sensor 1340 may measure a pressure in the tank 1300. The controller 30 may receive the pressure of the tank 1300 from the pressure sensor 1340.

After the state change operation S20, a circulation operation S30 may be further performed. As the temperature of the treatment fluid of the supercritical state increases, the pressure in the tank 1300 also increases. When the pressure in the tank 1300 exceeds a preset pressure, the circulation operation S30 is performed.

In the circulation operation S30, the treatment fluid SC stored in the tank 1300 is circulated along the circulation line 1400. In the circulation operation S30, the controller 30 controls the first valve 1410 to open. Accordingly, the treatment fluid SC in the supercritical state in the tank 1300 circulates along the circulation line 1400. During the circulation operation S30, the treatment fluid SC of the supercritical state passes through the temperature drop member 1420. The temperature of the treatment fluid SC of the supercritical state decreases after passing through the temperature drop member 1420. The temperature may be reduced by the compression of the treatment fluid SC by the contraction portion 1421 and the re-expansion of the treatment fluid SC by the expansion portion 1422. As the treatment fluid SC passes through the contraction portion 1421, its temperature decreases according to the Bernoulli principle. As the cross-sectional area of the contraction portion 1421 narrows in the longitudinal direction, the treatment fluid SC flows faster and the pressure is lowered to conserve kinetic energy.

The treatment fluid SC then passes through the expansion portion 1422. The treatment fluid SC, compressed in the contraction portion 1421, undergoes adiabatic expansion as it passes through the expansion portion 1422. In general, the fluid decreases in temperature during adiabatic expansion. Therefore, the treatment fluid SC decreases in temperature as it passes through the expansion portion 1422. Accordingly, the treatment fluid of the supercritical state may change state to a third state. The third state may be a gaseous state. Hereinafter, it is described that the third state is a gaseous state. The treatment fluid SC in the gaseous state is re-supplied back into the tank 1300 along the circulation line 1400. After re-supply, the state change operation S20 may be performed again.

In the supply operation S40, the treatment fluid SC of the supercritical state is supplied to the interior space 511 of the body 510. The controller 30 receives the temperature of the treatment fluid of the supercritical state from the temperature sensor 1330. In the case of dry treating the substrate, the controller 30 may open the first supply first valve 1410 and/or the second supply valve when the temperature of the treatment fluid of the supercritical state falls within a preset temperature range. Accordingly, the treatment fluid of the supercritical state may be supplied to the interior space 511. Subsequently, the introduction operation S10 may be performed again.

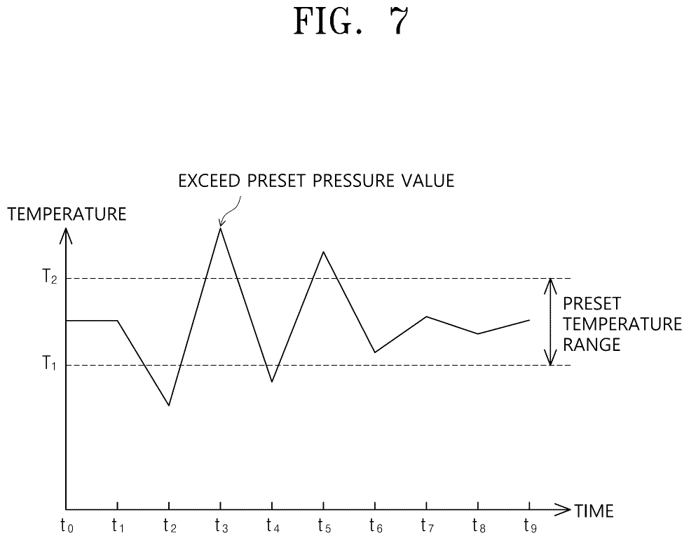

FIG. 7 is a graph illustrating the temperature change over time of a treatment fluid stored in a tank according to an exemplary embodiment of the present invention.

A treatment fluid of the supercritical state is supplied to the interior space 511 (t0 to t1). The treatment fluid SC in the liquid state is then introduced into the tank 1300. Since the treatment fluid SC is at a lower temperature than the treatment fluid of the supercritical state, the temperature of the treatment fluid decreases (t1 to t2). The temperature of the treatment fluid increases (t2 to t3) as the controller 30 heats the treatment fluid SC in the liquid state with the external heater 1310 and the internal heater 1320 to change the state of the treatment fluid SC to the supercritical state. The temperature of the treatment fluid SC continues to rise. The temperature of the treatment fluid SC may increase beyond a preset temperature range T1 to T2. Along with the temperature increase, the pressure in the tank 1300 may also increase. The controller 30 receives a pressure value in the tank 1300 from the pressure sensor 1340. When the pressure value exceeds a preset pressure, the controller 30 controls the first valve 1410 to open. This allows the treatment fluid SC of the supercritical state to circulate along the circulation line 1400. As the treatment fluid SC of the supercritical state passes through the temperature drop member 1420, the temperature of the treatment fluid SC of the supercritical state decreases and the treatment fluid SC of the supercritical state is changed to the treatment fluid SC of the gaseous state. The treatment fluid SC of the gaseous state is introduced back into the tank 1300. Because the treatment fluid SC of the gaseous state has a lower temperature than the treatment fluid SC of the supercritical state, the temperature of the treatment fluid SC in the tank decreases (t3 to t4). However, since the temperature of the treatment fluid SC of the gaseous state is higher than the treatment fluid SC in the liquid state, the temperature decrease width is smaller than when the treatment fluid SC in the liquid state is introduced. The controller 30 heats the external heater 1310 and the internal heater 1320 to change the state of the treatment fluid SC of the gaseous state to the supercritical state (t4 to t5). When the pressure value in the tank 1300 again exceeds the preset pressure during the heating process, the above process is repeated again (after t5). In one example, the above process may be repeated a plurality of times.

According to the exemplary embodiment of the present invention, the pressure of the tank 1300 and the temperature of the treatment fluid SC may be efficiently controlled without discharging the treatment fluid SC stored within the tank 1300 to the outside. Thus, the amount of treatment fluid SC used may be reduced. Furthermore, the temperature of the treatment fluid SC may be controlled within a certain range, thereby ensuring reproducibility of the drying process.

The support member 540 may support the substrate W in the interior space 511. The support member 540 may be configured to support an edge region of the substrate W in the interior space 511. For example, the support member 540 may be configured to support a bottom side of an edge region of the substrate W in the interior space 511.

The treatment fluid discharge unit 550 may discharge the treatment fluid SC to the outside from the interior space 511 of the body 510. The treatment fluid discharge unit 550 may include a fluid discharge line 551 and a discharge valve 553. One end of the fluid discharge line 551 may be in communication with the interior space 511. At least a portion of the fluid discharge line 551 may be provided in the lower body 514. The fluid discharge line 551 may be configured such that when the treatment fluid SC is discharged from the interior space 511, the treatment fluid SC flows in a direction from the top to the bottom of the interior space 511.

Additionally, the fluid discharge line 551 may be equipped with the discharge valve 553. The discharge valve 553 may be an on/off valve, such as an open/close valve. The outlet valve 553 may also be a flow regulating valve. The fluid discharge line 551 may be installed and arranged with a variety of materials, such as orifices, pressure sensors, temperature sensors, and pumps.

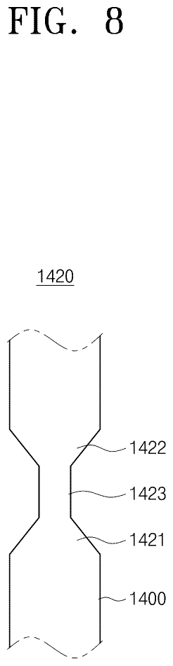

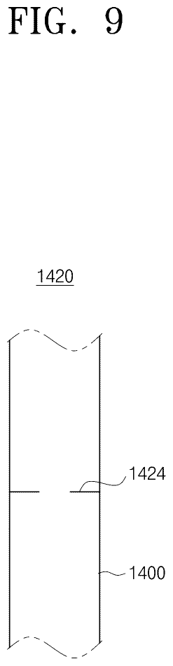

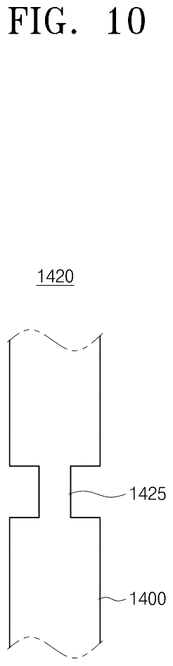

In the example described above, the present invention has been described based on the case where the temperature drop member 1420 includes the contraction portion 1421 and the expansion portion 1422 as an example, but the present invention is not limited thereto, and may be configured to reduce the temperature of the treatment fluid through the Venturi effect. For example, a connection portion 1423 may be provided to connect the contraction portion 1421 and the expansion portion 1422, as illustrated in FIG. 8. Also, instead of the contraction portion 1421 and the expansion portion 1422, an orifice 1424 may be provided, as illustrated in FIG. 9, and a passage 1425 having a narrower cross-sectional area than the cross-sectional area of the circulation line 1400 may be provided, as illustrated in FIG. 10.

In addition, the first supply line 1520, the second supply line 1530, or the line between the point at which the first supply line 1520 and the second supply line 1530 are connected to the tank 1300 as described in the examples above, may be equipped and disposed with a variety of materials, such as pressure sensors, temperature sensors, flow control valves, orifices, and heaters.

In addition, the above examples illustrate the removal of organic solvents remaining on the substrate W with the treatment fluid SC of the supercritical state. In contrast, however, the liquid being removed with the treatment fluid of the supercritical state may be a developer or other kind of treatment solution.

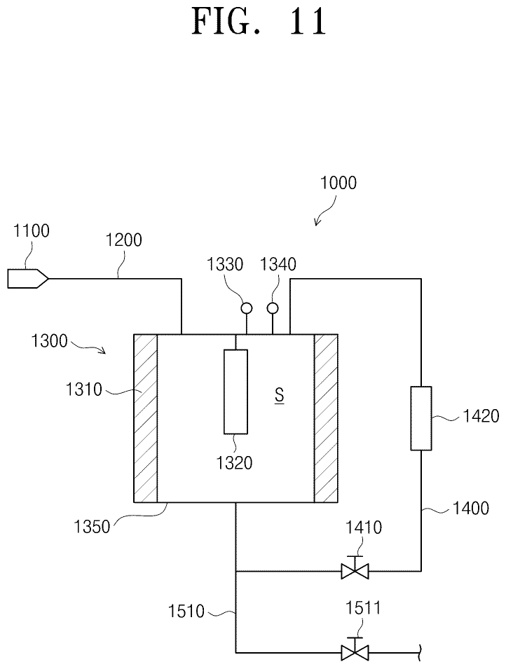

Further, in the examples described above, the main supply line and the circulation line are each described as being connected directly to the tank. However, in contrast, the main supply line may be connected to the circulation line as illustrated in FIG. 11.

Further, in the above examples, the second state is described as being a gaseous state. However, the present invention is not limited thereto, and the treatment fluid may be a supercritical or subcritical treatment fluid with a reduced temperature.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for treating a substrate, the apparatus comprising:
a chamber for providing a treatment space for treating a substrate; and
a treatment fluid supply unit for supplying a treatment fluid to the treatment space,
wherein the treatment fluid supply unit includes:
a tank for storing the treatment fluid;
a heating unit for heating the treatment fluid in the tank to change the treatment fluid from a first state to a second state;
an inlet line for introducing the treatment fluid in the first state into the tank;
a supply line for supplying the treatment fluid of the second state from the tank to the chamber;
a circulation line for circulating the treatment fluid in the tank;
a first valve installed in the circulation line; and
a temperature drop member installed in the circulation line to lower a temperature of the treatment fluid flowing through the circulation line.

2. The apparatus of claim 1, wherein the temperature drop member includes a temperature drop passage having a narrower area than an area of a passage through which the treatment fluid flows in the circulation line.

3. The apparatus of claim 1, wherein the temperature drop member includes an orifice.

4. The apparatus of claim 2, wherein the temperature drop passage includes:
a contraction portion having a progressively narrower cross-sectional area along a longitudinal direction of the temperature drop passage in a direction from upstream to downstream; and
an expansion portion having a progressively wider cross-sectional area along the longitudinal direction of the passage in a direction from upstream to downstream, and
the contraction portion is located upstream of the expansion portion.

5. The apparatus of claim 4, wherein the temperature drop passage further includes a connection portion connecting the contraction portion and the expansion portion, and
the connection portion has a constant cross-sectional area along the longitudinal direction of the temperature drop passage.

6. The apparatus of claim 1, wherein the temperature drop member is provided to change the treatment fluid of the first state to the treatment fluid of a third state.

7. The apparatus of claim 6, wherein the first state is a liquid state,
the second state is a supercritical state, and
the third state is a gaseous state.

8. The apparatus of claim 1, wherein the circulation line is provided in a separation state from the supply line.

9. The apparatus of claim 1, further comprising:
a pressure sensor for measuring a pressure in the tank; and
a controller,
wherein the controller receives a measurement value measured from the pressure sensor and controls the first valve based on the measurement value.

10. The apparatus of claim 9, wherein the controller controls the first valve to open when the measurement value exceeds a preset pressure.

11. The apparatus of claim 1, further comprising:
a second valve installed in the supply line to open and close the supply line;
a temperature sensor for measuring a temperature of the treatment fluid; and
a controller,
wherein the controller controls the second valve to open when the temperature measured by the temperature sensor satisfies a preset range when treating the substrate.

12. (canceled)

13. An apparatus for treating a substrate, the apparatus comprising:
a chamber for providing a treatment space for treating a substrate; and
a treatment fluid supply unit for supplying a treatment fluid to the treatment space,
wherein the treatment fluid supply unit includes:
a tank for storing the treatment fluid;
a pressure sensor for measuring a pressure in the tank;
a heating unit for heating the fluid to change the treatment fluid in the tank from a liquid state to a supercritical state,
an inlet line for introducing the treatment fluid of the liquid state into the tank;
a circulation line provided in a separation state from the supply line, and for circulating the treatment fluid in the tank;
a first valve installed in the circulation line to open and close the circulation line;
a temperature drop member installed in the circulation line to drop the temperature of the treatment fluid flowing through the circulation line;
a supply line for supplying the treatment fluid of the supercritical state from the tank to the chamber; and
a controller,
wherein the temperature drop member changes the treatment fluid of the supercritical state to a gaseous state, and
the controller receives a pressure value measured from the pressure sensor and, and opens the first valve when the pressure value exceeds a preset pressure.

14. The apparatus of claim 13, wherein the temperature drop member includes:
a contraction portion progressively smaller in a direction from upstream to downstream of the circulation line;
an extension portion progressively larger in a direction from upstream to downstream of the circulation line; and
a connection portion connecting the contraction portion and the expansion portion, and
the contraction portion is located upstream of the expansion portion.

15. The apparatus of claim 13, wherein the temperature drop member includes an orifice.
